(19) United States
(12) Patent Application Publication
(10) Pub. No.: US 2025/0105110 A1
(43) Pub. Date: Mar. 27, 2025

(54) SEMICONDUCTOR DEVICE AND POWER CONVERSION DEVICE

(71) Applicant: HITACHI ASTEMO, LTD., Ibaraki (JP)

(72) Inventors: Nobutake TSUYUNO, Tokyo (JP); Yujiro KANEKO, Hitachinaka-shi (JP); Yusuke TAKAGI, Hitachinaka-shi (JP)

(21) Appl. No.: 18/726,097

(22) PCT Filed: Dec. 28, 2022
(86) PCT No.: PCT/JP2022/048680

§ 371 Date: Jul. 1, 2024

(30) Foreign Application Priority Data
Feb. 25, 2022 (JP) 2022-028605

(51) Int. Cl. H01L 23/495; H01L 23/00; H01L 23/31; H01L 23/367; H01L 25/07

(52) U.S. Cl. CPC H01L 23/49586; H01L 23/3107; H01L 23/49562; H01L 25/072; H01L 23/367; H01L 24/08; H01L 2224/08057; H01L 2224/08245; H01L 2924/1203

(57) ABSTRACT

A semiconductor device has a conductor plate to which a plurality of semiconductor elements are joined; an insulation sheet which is bonded to the opposite face of the conductor plate from the side facing the semiconductor elements; and a resin member which seals the semiconductor elements, the insulation sheet and the conductor plate. The conductor plate includes element joining regions to which the semiconductor elements are respectively joined, and a connection region which is provided between the element joining regions. The surface of the element joining regions of the conductor plate on the side facing the insulation sheet protrudes beyond the surface of the connection region on the side facing the insulation sheet and is bonded to the insulation sheet. The resin member is filled between the insulation sheet and the surface of the connection region of the conductor plate on the side facing the insulation sheet.

### TECHNICAL FIELD

The present invention relates to a semiconductor device and a power conversion device.

### BACKGROUND ART

A power conversion device that employs semiconductor element switching affords high conversion efficiency, and thus is widely used for consumer use, in-vehicle use, railway use, transformer facilities, and the like. Such power conversion devices include a semiconductor device. A semiconductor device includes a semiconductor element, a conductor plate to which the semiconductor element is joined, and an insulation sheet which is bonded to the surface of the conductor plate on the opposite side from the semiconductor element side. These components are sealed by means of a resin member. In particular, in vehicle-mounted applications, a semiconductor device is required to have high reliability.

PTL 1 discloses an electric circuit body in which a sheet-like member (insulation sheet) having a resin insulation layer, a conductor plate, and a semiconductor element are covered with a sealing resin by means of transfer molding.

### CITATION LIST

### Patent Literature

PTL 1: Japanese Patent Application Laid-Open No. 2021 048255

### SUMMARY OF INVENTION

### Technical Problem

The semiconductor device disclosed in PTL 1 is faced with the problem of the insulation properties provided by the insulation sheet.

### Solution to Problem

A semiconductor device of the present invention includes: a plurality of semiconductor elements; a conductor plate to which the plurality of semiconductor elements are joined; an insulation sheet which is bonded to the face of the conductor plate on the opposite side from the side of the plurality of semiconductor elements; and a resin member that seals the plurality of semiconductor elements, the insulation sheet, and the conductor plate, wherein the conductor plate includes a plurality of element joining regions to which each of the plurality of semiconductor elements is joined, and a connection region provided between the plurality of element joining regions, wherein the insulation sheet-side surface of the conductor plate in the element joining regions protrudes from the insulation sheet-side surface of the connection region and is bonded to the insulation sheet, and wherein the resin member is added between the insulation sheet and the insulation sheet-side surface of the conductor plate in the connection region.

### Advantageous Effects of Invention

According to the present invention, it is possible to provide a highly reliable semiconductor device having enhanced insulation properties afforded by an insulation sheet.

### BRIEF DESCRIPTION OF DRAWINGS

FIG. 1 is a plan view of an embodiment of an electric circuit body.

FIG. 2 is a cross-sectional view of the electric circuit body taken along line X-X.

FIG. 3 is a cross-sectional view of the electric circuit body taken along line Y-Y.

FIG. 4 is a cross-sectional perspective view of a semiconductor device.

FIG. 5 is a semi-transparent plan view of the semiconductor device.

FIG. 6 is a circuit diagram of the semiconductor device.

FIGS. 7(a) to 7(d) are cross-sectional views to illustrate a manufacturing process of the semiconductor device.

FIGS. 8(a) to 8(c) are cross-sectional views schematically illustrating a principle for improving insulating properties.

FIG. 9 is a cross-sectional view schematically illustrating a principle for improving insulating properties in a process for injecting a resin member.

FIGS. 10(a) to 10(c) are cross-sectional views schematically illustrating a comparative example.

FIG. 11 is a cross-sectional view schematically showing a comparative example in the process of injecting the resin member.

FIGS. 12(a) and 12(b) are a semi-transparent plan view and a cross-sectional view of a semiconductor device according to a modification.

FIG. 13 is a diagram illustrating a relationship between a shrinkage amount of the resin member and temperature.

FIG. 14 is a circuit diagram of a power conversion device employing a semiconductor device.

FIG. 15 is an external perspective view of the power conversion device.

FIG. 16 is a cross-sectional perspective view taken along line XV-XV of the power conversion device.

### DESCRIPTION OF EMBODIMENTS

Hereinafter, embodiments of the present invention will be described with reference to the drawings. Note that the descriptions and drawings hereinbelow are examples to illustrate the present invention, and omissions and simplifications are made, as appropriate, to clarify the invention. The present invention can also be carried out in various other modes. Unless otherwise specified, each constituent element may be singular or plural.

In order to facilitate understanding of the invention, the position, size, shape, range, and the like of each constituent element illustrated in the drawings may not represent the actual position, size, shape, range, and the like. Therefore, the present invention is not necessarily limited to or by the position, size, shape, range, and the like disclosed in the drawings.

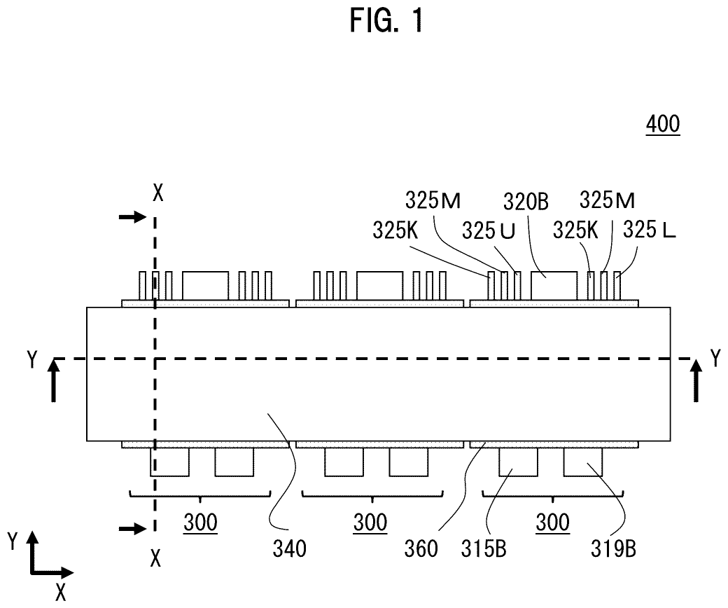

FIG. 1 is a plan view of an electric circuit body 400.

The electric circuit body 400 includes three semiconductor devices 300 and a cooling member 340 for cooling the semiconductor devices 300.

The semiconductor device 300 includes components the details of which will be provided further below, namely, a semiconductor element, a conductor plate to which the semiconductor element is joined, and an insulation sheet which is bonded to the surface of the conductor plate on the opposite side from the semiconductor element side. These components are sealed by means of a resin member 360. The semiconductor device 300 mutually converts DC power and AC power using a semiconductor element. Because the semiconductor device 300 generates heat by energization of the semiconductor element, the semiconductor device is cooled by the cooling member 340. Refrigerant flows inside the cooling member 340, and water, antifreeze liquid obtained by mixing ethylene glycol with water, or the like, is used as the refrigerant.

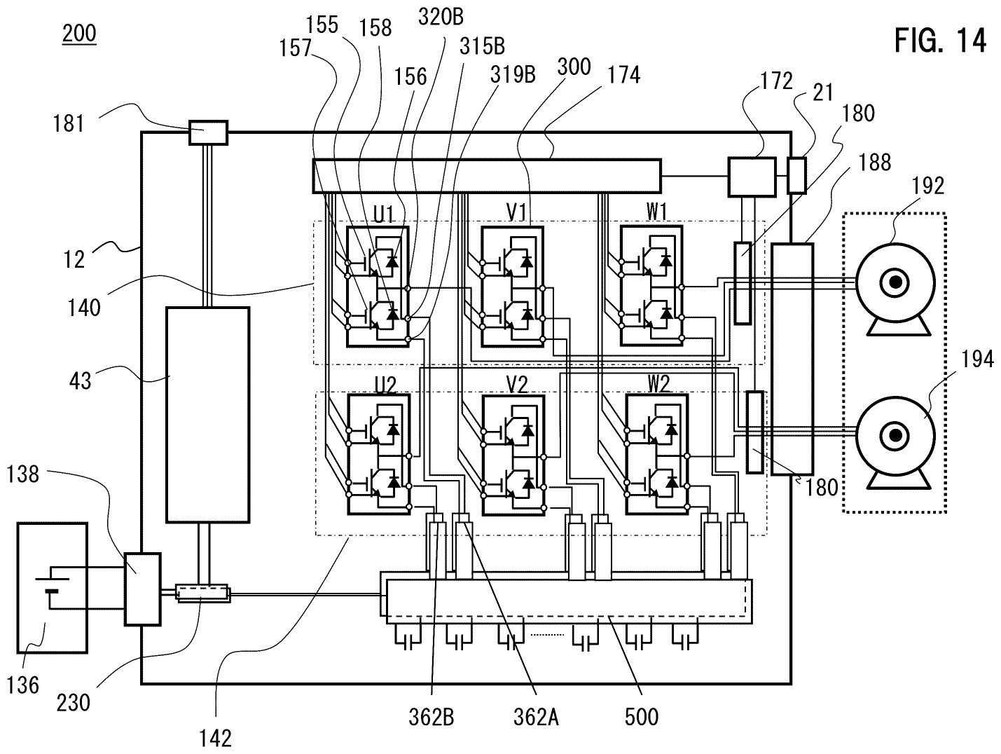

The semiconductor device 300 includes power terminals through which a large current flows, such as a positive electrode-side terminal 315B and a negative electrode-side terminal 319B connected to a capacitor module 500 (see FIG. 14) of a DC circuit, and an AC-side terminal 320B connected to motor generators 192 and 194 (see FIG. 14) of an AC circuit. In addition, a lower arm gate terminal 325L, a mirror emitter signal terminal 325M, and a Kelvin emitter signal terminal 325K are provided to correspond to the semiconductor element of the lower arm. Signal terminals, which are used to control the semiconductor device such as an upper arm gate terminal 325U, the mirror emitter signal terminal 325M, and the Kelvin emitter signal terminal 325K, are provided to correspond to the semiconductor element of the upper arm.

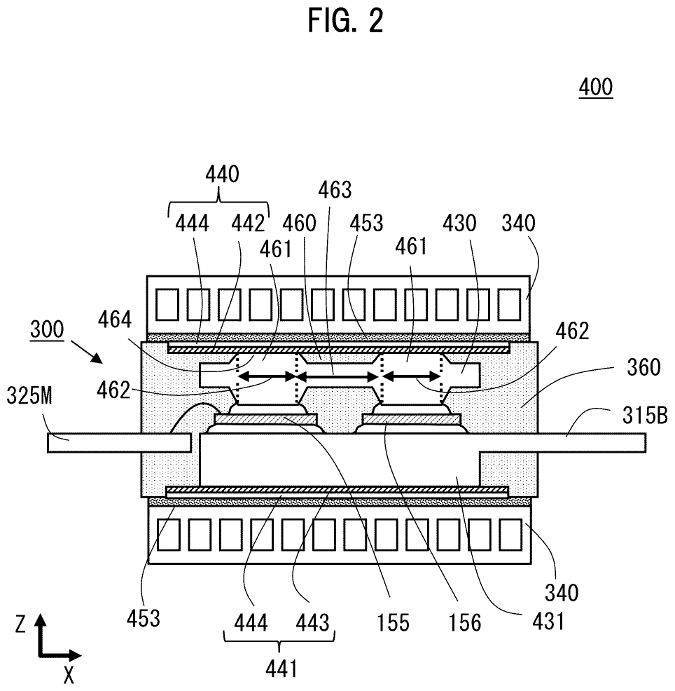

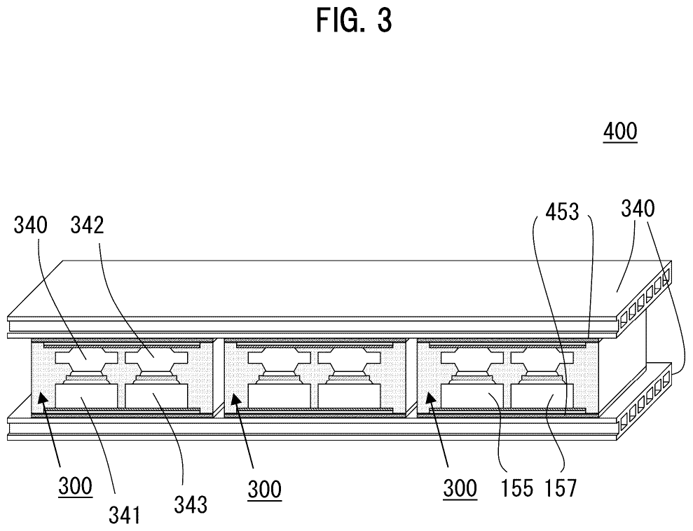

FIG. 2 is a cross-sectional view taken along line X-X of the electric circuit body 400 shown in FIG. 1. FIG. 3 is a cross-sectional view taken along line Y-Y of the electric circuit body 400 shown in FIG. 1.

As first power semiconductor elements 155 and 156 forming the upper arm circuit, an active element 155 and a diode 156 are provided. Si, SiC, GaN, GaO, C, or the like can be used as the active element 155. In a case where the body diode of the active element 155 is used, the separate diode may be omitted. The collector side of the first power semiconductor elements 155 and 156 is joined to a second conductor plate 431. For this joining, solder or sintered metal may be used. A first conductor plate 430 is joined to the emitter side of the first power semiconductor elements 155 and 156. As second power semiconductor elements 157 and 158 forming the lower arm circuit, an active element 157 and a diode 158 are provided. The collector side of the second power semiconductor elements 157 and 158 is joined to a fourth conductor plate 433. A third conductor plate 432 is joined to the emitter side of the second power semiconductor elements 157 and 158.

The conductor plates 430, 431, 432, and 433 are not particularly limited as long as they are made of a material having high electrical conductivity and thermal conductivity, but a copper-based or aluminum-based material is desirable. These materials may be used alone, but may be plated with Ni, Ag, or the like in order to improve bondability to solder or to a sintered metal.

In addition to the role of passing current, the conductor plates 430, 431, 432, and 433 fulfill the role of heat transfer members for transferring heat generated by the power semiconductor elements 155, 156, 157, and 158 to the cooling member 340. Because the conductor plates 430, 431, 432, and 433 and the cooling member 340 have different potentials, insulation sheets 440 and 441 are arranged therebetween. A heat conduction member 453 is disposed between the insulation sheets 440 and 441 and the cooling member 340 in order to reduce contact thermal resistance. The power semiconductor elements 155, 156, 157, and 158, the conductor plates 430, 431, 432, and 433, and the insulation sheets 440 and 441 are sealed with the resin member 360 by means of transfer molding.

The insulation sheet 440 has a laminated structure of a resin insulation layer 442 and a metal foil 444, and the insulation sheet 441 has a laminated structure of a resin insulation layer 443 and the metal foil 444. However, the insulation sheets 440 and 441 may be the resin insulation layers 442 and 443 alone, respectively. In a case where the insulation sheets 440 and 441 have a laminated structure of the resin insulation layers 442 and 443 and the metal foil 444, the metal foil 444 is disposed on the side in contact with the heat conduction member 453. The resin insulation layers 442 and 443 of the insulation sheets 440 and 441 are not particularly limited as long as they have adhesiveness with the conductor plates 430, 431, 432, and 433, but epoxy resin-based resin insulation layers 442 and 443 in which a powdery inorganic filler is dispersed are desirable. This is because the balance between adhesiveness and heat dissipation is good. In the transfer molding process, when the insulation sheets 440 and 441 are mounted on a mold, a metal foil 444 is provided on a contact surface between the insulation sheets 440 and 441 and the mold in order to prevent adhesion to the mold. In a case where a release sheet is used to prevent adhesion to the mold, a step of peeling off the release sheet after transfer molding is required because the release sheet has poor thermal conductivity, but in the case of the metal foil 444, the step of peeling off the release sheet after transfer molding is rendered unnecessary by selecting a copper-based or aluminum-based metal having high thermal conductivity. By performing transfer molding including the insulation sheets 440 and 441, the end portions of the insulation sheets 440 and 441 are covered with the resin member 360, and thus there is the advantageous effect of improving reliability.

As illustrated in FIG. 2, each of the conductor plates 430, 431, 432, and 433 has an element joining region 462 joining the power semiconductor elements 155, 156, 157, and 158 and a connection region 463 connecting the element joining region 462, and has a projection 461 immediately above the element joining region 462.

The projection 461 adheres to the insulation sheet 440 in a close contact region 464. In the connection region 463, a resin filling space 460 is formed between the insulation sheet 440 and the first conductor plate 430. The resin filling space 460 is filled with a resin member 360 in a transfer molding process to be described below, and is connected to the resin member 360 that seals the power semiconductor elements 155, 156, 157, and 158, the insulation sheet 440, and the conductor plates 430, 431, 432, and 433. Because the resin insulation layer 442 of the insulation sheet 440 and the resin member 360 are simultaneously cured in the transfer molding process, the resin components of the resin insulation layer 442 and the resin member 360 penetrate each other and have high adherence in comparison with a case where the resin insulation layer 442 and the resin member 360 are bonded to each other after curing. The resin filling space 460 desirably has a thickness of 300 μm or more enabling sufficient filling with the resin member 360. From the viewpoint of insulating properties, the thickness of the resin insulation layer 442 of the insulation sheet 440 is preferably greater.

The conductor plates 430, 431, 432, and 433 are desirably made of a material having high electrical conductivity and high thermal conductivity, and it is also possible to use a metal-based material such as copper or aluminum, or a composite material of a metal-based material and highly thermally conductive diamond, carbon, ceramic, or the like. The connection region 463 of the conductor plates 430, 431, 432, and 433 is produced by, for example, a recess formed by press working, cutting by machining or laser machining, or a connection of a low rigidity member.

The cooling member 340 is desirably made of a highly thermally conductive and lightweight aluminum. The cooling member 340 is prepared by extrusion molding, forging, brazing, or the like.

The heat conduction member 453 is not particularly limited as long as they is made of a material having high thermal conductivity, but it is preferable to use a high thermal conduction material such as a metal, a ceramic, or a carbon-based material in combination with a resin material. This is because a resin material compensates between a high thermal conductivity material and a high thermal conductivity material, between a high thermal conductivity and the cooling member 340, and between a highly thermally conductive member and the insulation sheets 440 and 441, and thus the contact thermal resistance is reduced.

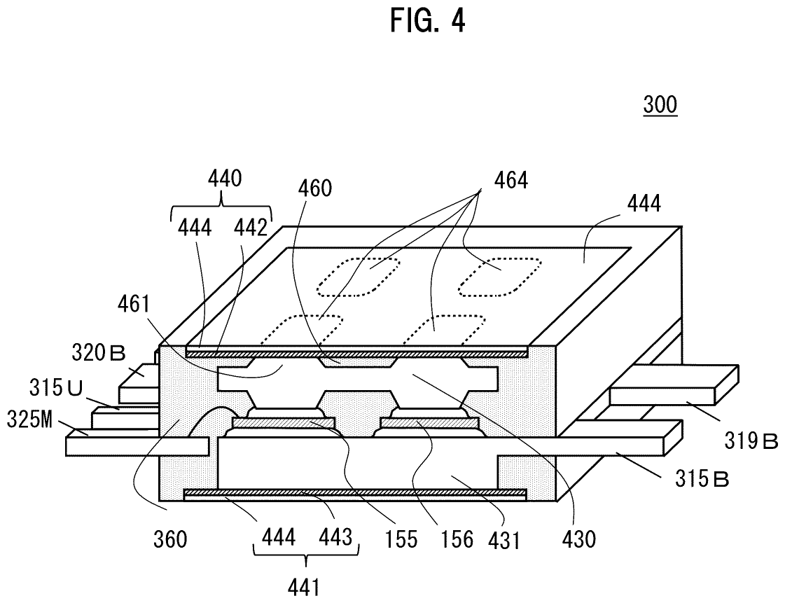

FIG. 4 is a cross-sectional perspective view of the semiconductor device 300.

The projection 461 of the conductor plate 430 adheres to the insulation sheet 440 in the close contact region 464. Further, the resin filling space 460 is formed between the insulation sheet 440 and the first conductor plate 430, and the resin filling space 460 is filled with the resin member 360.

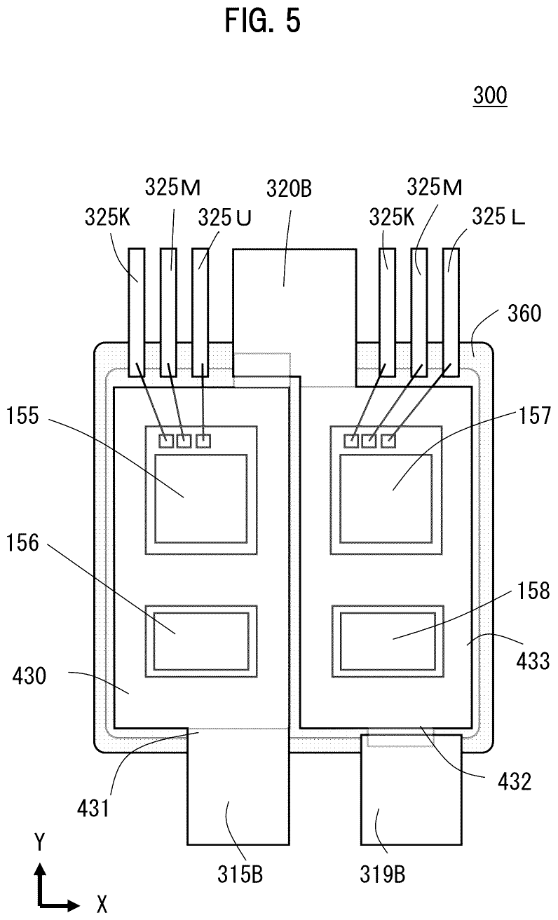

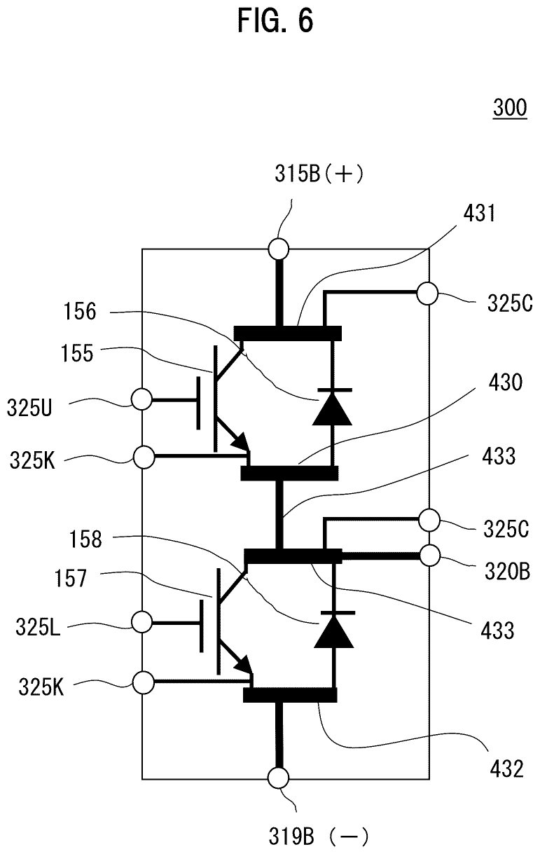

FIG. 5 is a semi-transparent plan view of the semiconductor device 300. FIG. 6 is a circuit diagram of the semiconductor device 300.

As shown in FIGS. 5 and 6, the positive electrode-side terminal 315B is outputted from the collector side of the upper arm circuit, and is connected to the positive electrode side of the battery or the capacitor. The upper arm gate terminal 325U is outputted from the gate of the active element 155 of the upper arm circuit, and the upper-arm Kelvin emitter signal terminal 325K is outputted from the emitter sense of the active element 155 of the upper arm circuit. The negative electrode-side terminal 319B is outputted from the emitter side of the lower arm circuit, and is connected to the negative electrode side of the battery or the capacitor or to GND. The lower arm gate terminal 325L is outputted from the gate of the active element 157 of the lower arm circuit, and the lower-arm Kelvin emitter signal terminal 325K is outputted from the emitter sense of the active element 157 of the lower arm circuit. The AC-side terminal 320B is outputted from the collector side of the lower arm circuit and is connected to the motor. In a case where the neutral point is grounded, the lower arm circuit is connected not to GND but to the negative electrode side of the capacitor.

In addition, a conductor plate (upper arm circuit emitter side) 430 and a conductor plate (upper arm circuit collector side) 431 are arranged above and below the active element 155 and the diode 156 of the power semiconductor element (upper arm circuit). A conductor plate (lower arm circuit emitter side) 432 and a conductor plate (lower arm circuit collector side) 433 are arranged above and below the active element 157 and the diode 158 of the power semiconductor element (lower arm circuit).

The semiconductor device 300 according to the present embodiment has a 2 in 1 structure in which two arm circuits, namely, an upper arm circuit and a lower arm circuit, are integrated into one module. In addition, a structure in which a plurality of upper arm circuits and lower arm circuits are integrated into one module may be used. In this case, the number of output terminals from the semiconductor device 300 can be reduced and downsized.

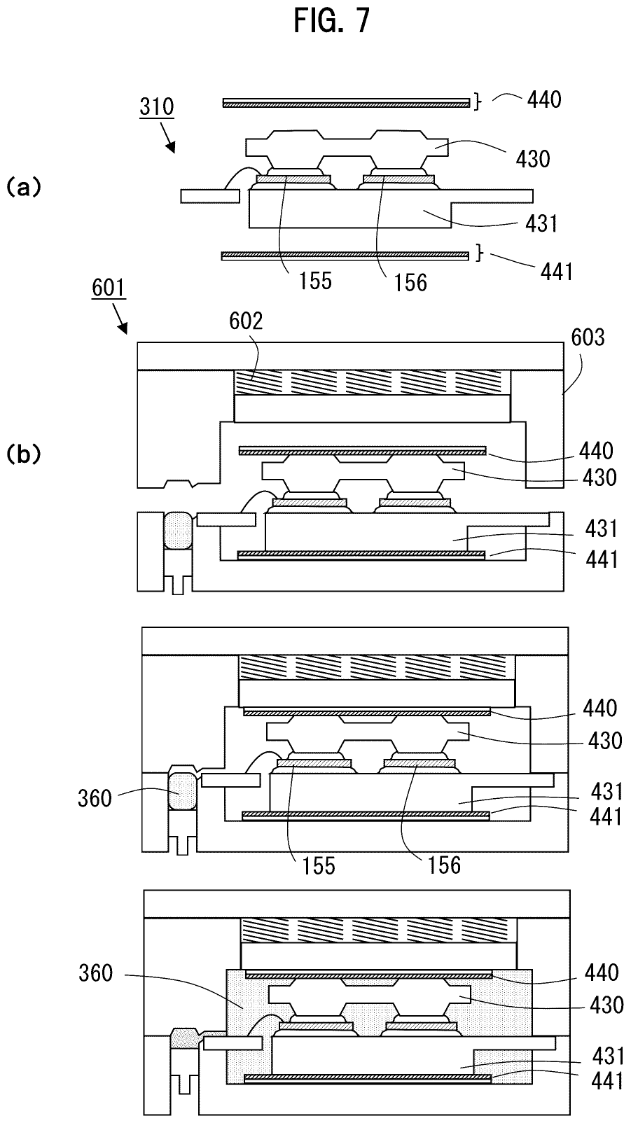

FIGS. 7(a) to 7(d) are cross-sectional views to illustrate a manufacturing process of the semiconductor device 300. Similarly to FIG. 2, FIGS. 7(a) to 7(d) are cross-sectional views of one module taken along line X-X.

FIG. 7(a) is a temporary fitting step. The collector sides of the power semiconductor elements 155 and 156 are connected to the conductor plates 430 and 431, and the gate electrodes of the power semiconductor elements 155 and 156 are connected through wire bonding. Further, the emitter side of the power semiconductor elements 155 and 156 is connected to the conductor plates 430 and 431 to manufacture the circuit body 310. Thereafter, the insulation sheets 440 and 441 are temporarily attached to the conductor plates 430 and 431. The temporary bonding is to temporarily attach the insulation sheets 440 and 441 using the adhesive force of the insulation sheets 440 and 441 under the condition that there is room for curing and bonding the insulation sheets in the subsequent transfer molding process.

FIGS. 7(b) to 7(d) illustrate a transfer molding process. The transfer molding device 601 includes a spring 602 in a mold 603. Using the spring 602, even if the height of the circuit body 310 varies, a predetermined load can be applied by the force of the spring 602 without applying excessive pressure to the power semiconductor elements 155 and 156. The transfer molding device 601 includes a vacuum degassing mechanism (not illustrated). Through vacuum degassing, even when the resin member 360 or the like winds in voids, the voids can be compressed to be small, and the insulating properties can be improved. In addition, by covering the circuit body 310 with a release film (not illustrated), it is possible to protect the resin burr from penetrating the spring drive unit and the like.

As shown in FIG. 7(b), the circuit body 310 on which the insulation sheets 440 and 441 are temporarily attached is set in the mold 603, which is pre-heated to a constant temperature state of 175° C. Next, as illustrated in FIG. 7(c), the upper and lower molds 603 are clamped. At this time, the insulation sheets 440 and 441 and the conductor plates 430 and 431 are pressed and brought into close contact with each other by the spring 602. The conductor plate 431 located on the collector side is pressed toward the lower mold 603 when a terminal portion on the outer periphery of the conductor plate 431 is clamped by the mold, and is added to the force of the spring 602. Therefore, the conductor plate is crimped to the insulation sheet 441 with a stronger force than the conductor plate 430 located on the emitter side. The conductor plate 430 located on the emitter side is crimped to the insulation sheet 440 by the force of the spring 602, and the force of the spring 602 is also applied to the power semiconductor elements 155 and 156. For this reason, when the power semiconductor elements 155 and 156 are pressurized with a strong force in order to improve the insulation properties thereof, an excessive pressure is applied to the power semiconductor elements. In the present embodiment, details will be described below, but by providing the resin filling space 460, the insulating properties afforded by the insulation sheets 440 and 441 are enhanced without excessively pressurizing the power semiconductor elements 155 and 156.

Thereafter, as shown in FIG. 7(d), the resin member 360 is injected into the mold 603. Subsequently, the resin-sealed semiconductor device 300 is extracted from the transfer molding device 601, and post-curing is performed at 175° C. for 2 hours or more. Next, the cooling member 340 is joined via the heat conduction member 452 to manufacture the electric circuit body 400.

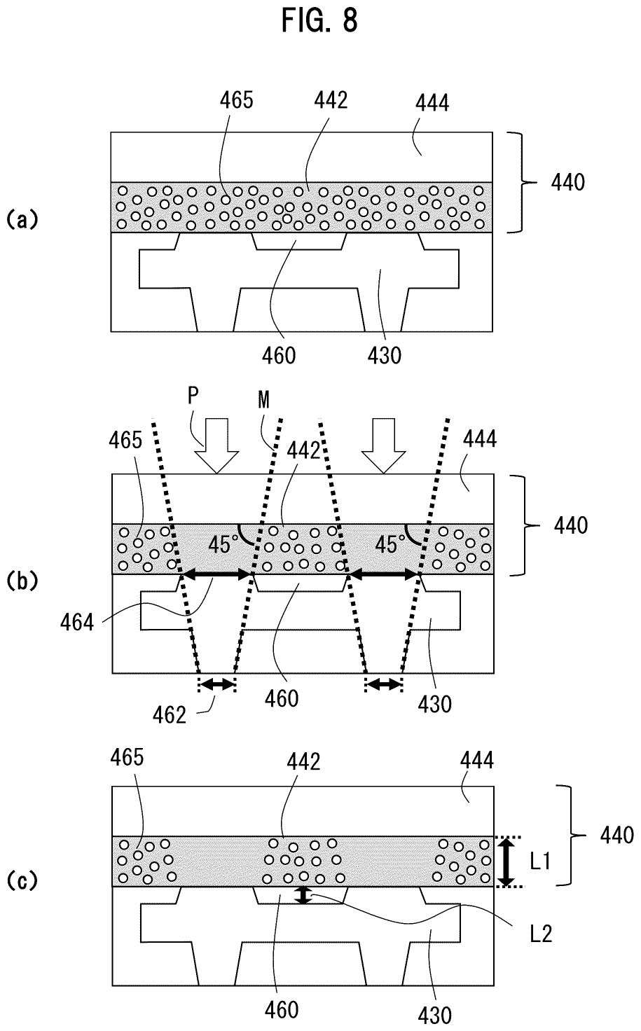

FIGS. 8(a) to 8(c) are cross-sectional views schematically illustrating the principle of improving insulation properties in the transfer molding process illustrated in FIGS. 7(b) to 7(d). In order to facilitate understanding, FIGS. 8(a) to 8(c) partially illustrate the insulation sheet 440 and the conductor plate 430 with the thickness of the insulation sheet 440 enlarged to be greater than the thickness of the conductor plate 430.

The resin insulation layer 442 of the insulation sheet 440 is filled with a large number of fillers (not illustrated) in a resin component such as an epoxy resin in order to afford high thermal conductivity. Therefore, as shown in FIG. 8(a), minute voids 465 may exist in the vicinity of the interface between the resin component and the filler. Such voids 465 cause a reduction in the insulating properties of the insulation sheet 440. As illustrated in FIG. 8(b), when clamping is performed using the transfer molding device 601 and the force P of the spring 602 acts, the load spreads from the element joining region 462 at an angle of about 45 degrees with respect to the plate thickness direction of the conductor plate 430. On the outside of this 45-degree line M, the load due to the force P of the spring 602 is greatly attenuated. By setting the close contact region 464 between the conductor plate 430 and the insulation sheet 440 to the inside of the line where the load spreads from the element joining region 462 at an angle of about 45 degrees with respect to the plate thickness of the conductor plate 430, the load by the force P of the spring 602 can be efficiently applied to the close contact region 464. A load is efficiently applied on the inside of the 45-degree line M to the resin insulation layer 442 in contact with the close contact region 464. Under this load, the voids 465 in the resin insulation layer 442 of the insulation sheet 440 are compressed, and the size of the voids 465 is reduced, thereby improving the insulating properties of the insulation sheet 440. On the outside of this 45-degree line M, the voids 465 in the resin insulation layer 442 remain without being compressed, but because the voids 465 immediately above the close contact region 464, which has a high electric field strength, are compressed, the insulating properties of the insulation sheet 440 are improved.

In addition, as illustrated in FIG. 8(c), by setting the thickness L2 of the resin filling space 460 to be equal to or greater than the thickness L1 of the resin insulation layer 442, the resin member 360 added in the resin filling space 460 acts as an insulation layer, and insulating properties can be secured even if the voids 465 remain, without being compressed, in the resin insulation layer 442 facing the resin filling space 460. In FIG. 8(c), because the thickness of the insulation sheet 440 is shown as greater than the thickness of the conductor plate 430, the thickness L2 of the resin filling space 460 is shown as smaller than the thickness L1 of the resin insulation layer 442; however, in actuality, as described above, the thickness L2 of the resin filling space 460 is equal to or greater than the thickness L1 of the resin insulation layer 442. In a case where the insulation sheet 440 is composed of the resin insulation layer 442 alone, the thickness L2 of the resin filling space 460 is equal to or greater than the thickness L1 of the insulation sheet 440.

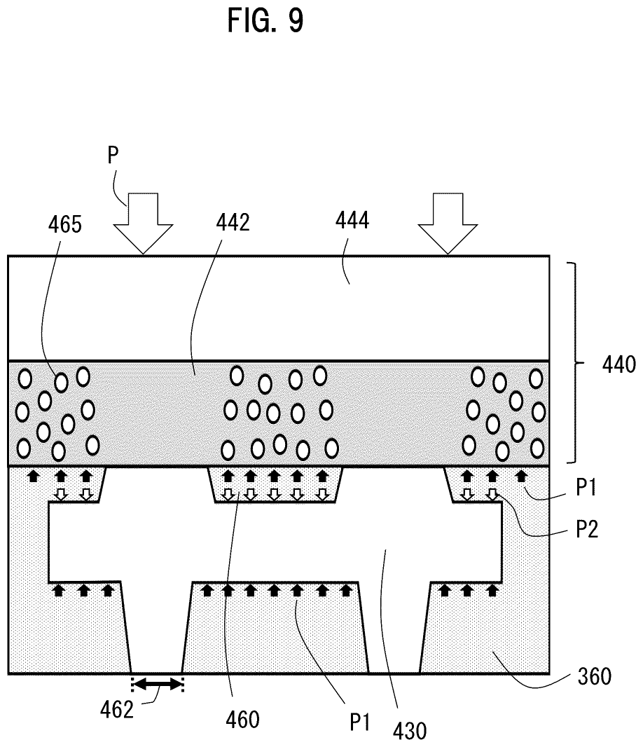

FIG. 9 is a cross-sectional view schematically illustrating the principle of improving the insulating properties in the process of injecting the resin member in the transfer molding process illustrated in FIG. 7(d). Similarly to FIGS. 8(a) to 8(c), in order to facilitate understanding, the insulation sheet 440 and the conductor plate 430 are partially illustrated with the thickness of the insulation sheet 440 enlarged to be greater than the thickness of the conductor plate 430.

When the resin member 360 is injected in the transfer molding process, the molding pressure acts in all directions as a hydrostatic pressure while the resin member 360 is in a liquid state. Among the hydrostatic pressures, a force acting upward in FIG. 9 is indicated by a black arrow as a molding pressure P1. In FIG. 9, the force acting downward is indicated by a white arrow as a molding pressure P2. In the resin filling space 460, the molding pressure P1 acts in a direction of compressing the insulation sheet 440. In addition, when attention is paid to the conductor plate 430, the molding pressure P1 applied to the conductor plate 430 from the lower side to the upper side is canceled by the molding pressure P2 from the resin member 360 that has penetrated the resin filling space 460, and the force with which the conductor plate 430 is pushed up is reduced. When a force in the peeling direction is applied to the element joining region 462 joining the power semiconductor elements 155 and 156, there is a concern that a joining material, such as solder, which joins the element joining region 462, will be peeled off. Therefore, the force P of the spring 602 needs to be increased to oppose the molding pressure P1 applied to the conductor plate 430 in an upward direction from the lower side thereof. As described above, by providing the resin filling space 460, the force with which the conductor plate 430 is pushed up by the molding pressure P1 is reduced, and hence there is the advantageous effect of reducing the force P of the spring 602. By reducing the force P of the spring 602, there are effects of reducing the cost of the transfer molding device 601 by simplifying the mold structure and reducing the cost of the spring 602. Furthermore, because the power semiconductor elements 155 and 156 are not excessively pressurized, there is an advantageous effect of an excellent yield of the semiconductor device 300.

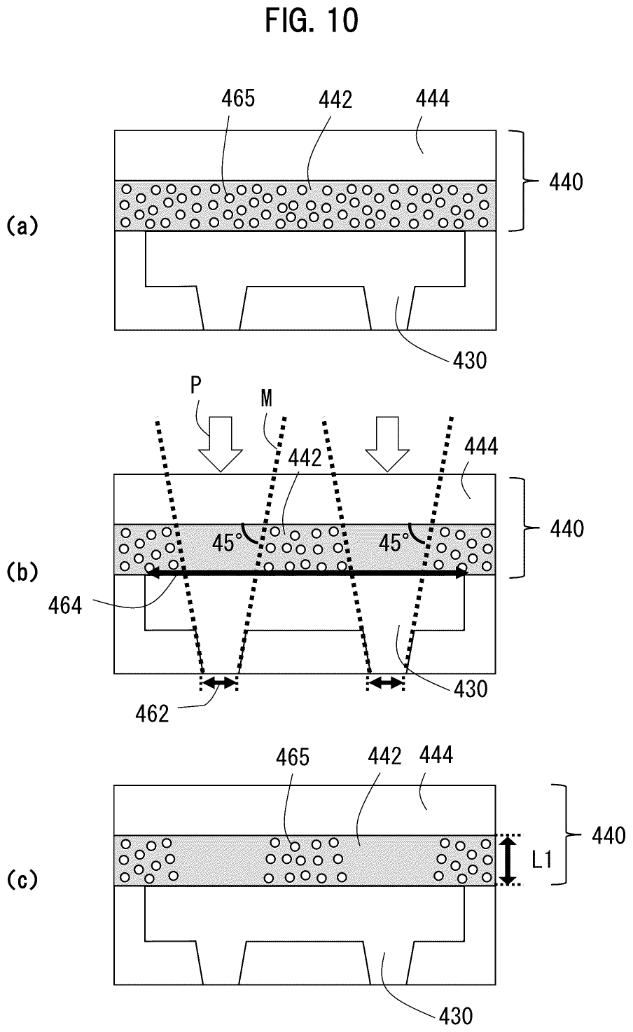

FIGS. 10(a) to 10(c) are cross-sectional views schematically illustrating a comparative example in the transfer molding process. In this comparative example, an example of a case where the resin filling space 460 is not provided and the present embodiment is not applied is illustrated. Similarly to FIGS. 8(a) to 8(c), in order to facilitate understanding, the insulation sheet 440 and the conductor plate 430 are partially illustrated with the thickness of the insulation sheet 440 enlarged to be greater than the thickness of the conductor plate 430.

The insulation sheet 440 is filled with a large number of fillers (not illustrated) in a resin component such as an epoxy resin in order to provide high thermal conductivity. Therefore, as shown in FIG. 10(a), minute voids 465 may exist in the vicinity of the interface between the resin component and the filler. Such voids 465 cause a reduction in the insulating properties. As illustrated in FIG. 10(b), when clamping is performed using the transfer molding device 601 and the force P of the spring 602 acts, the load spreads from the element joining region 462 at an angle of about 45 degrees with respect to the plate thickness direction of the conductor plate 430. On the outside of this 45-degree line M, the load due to the force P of the spring 602 is greatly attenuated. A load is also applied to the resin insulation layer 442 of the insulation sheet 440 on the inside of the 45-degree line M. Voids 465 in the resin insulation layer 442 are compressed by this load.

Meanwhile, on the outside of the 45-degree line M, the voids 465 in the resin insulation layer 442 remain without being compressed. In this comparative example, because the resin filling space 460 is not provided, the close contact region 464 is also further outside the 45-degree line M than the element joining region 462. For this reason, immediately above the close contact region 464 having high electric field strength, there is a region in which voids are not compressed, and thus the insulation properties are then low. In addition, as illustrated in FIG. 10(c), because the resin filling space 460 is not provided, only the thickness L1 of the resin insulation layer 442 functions as an insulation layer. Therefore, when the thickness L1 of the resin insulation layer 442 is increased in order to improve the insulation properties, the thermal resistance from the conductor plate 430 to the cooling member 340 via the insulation sheet 440 increases, and hence the heat dissipation of the semiconductor device 300 decreases.

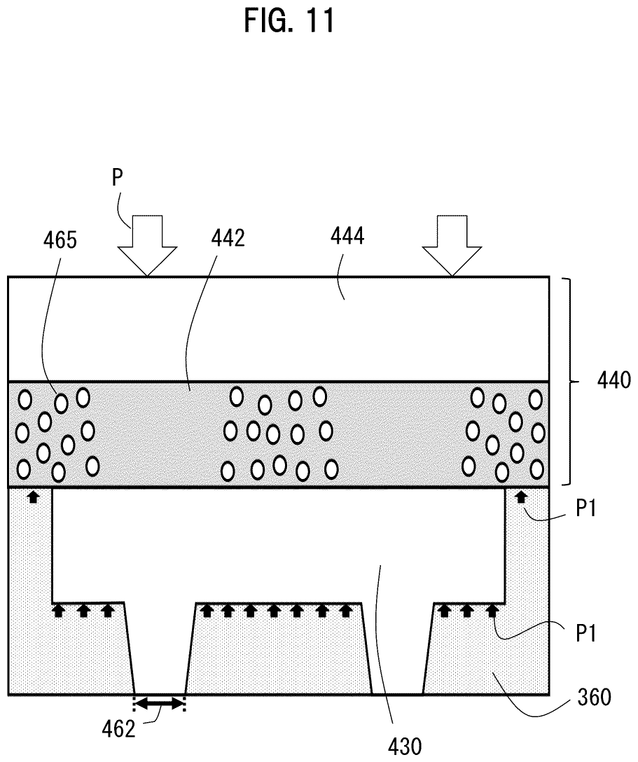

FIG. 11 is a cross-sectional view schematically showing the principle of insulating properties in a comparative example in the process of injecting the resin member in the transfer molding process shown in FIG. 7(d). In this comparative example, an example of a case where the resin filling space 460 is not provided and the present embodiment is not applied is illustrated. Similarly to FIGS. 8(a) to 8(c), in order to facilitate understanding, the insulation sheet 440 and the conductor plate 430 are partially illustrated with the thickness of the insulation sheet 440 enlarged to be greater than the thickness of the conductor plate 430.

When the resin member 360 is injected in the transfer molding process, the molding pressure acts in all directions as a hydrostatic pressure while the resin member 360 is in a liquid state. Among the hydrostatic pressures, a force acting upward in FIG. 11 is indicated by a black arrow as the molding pressure P1. When attention is paid to the conductor plate 430, the conductor plate 430 is pushed up by the molding pressure P1. When a force in the peeling direction is applied to the element joining region 462 joining the power semiconductor elements 155 and 156, there is a concern that a joining material such as solder, which joins the element joining region 462, will be peeled off. Therefore, the force P of the spring 602 needs to be increased to oppose the molding pressure P1. When the force P of the spring 602 is increased, the cost of the transfer molding device 601 increases, and the power semiconductor elements 155 and 156 are excessively pressurized, and hence the yield of the semiconductor device 300 deteriorates. For this reason, it is necessary to suppress the molding pressure P1 to be low, but the compression of the voids 465 becomes insufficient due to the reduction in the molding pressure P1, and as a result, the insulation properties of the insulation sheet 440 are then low.

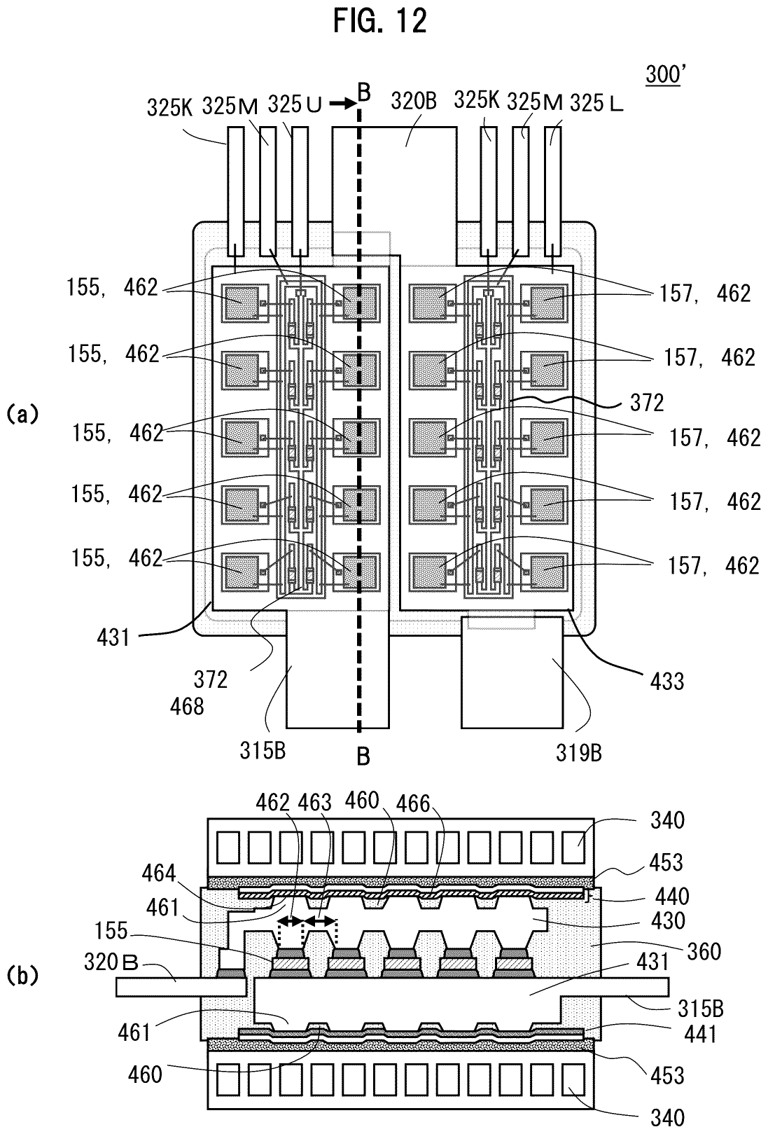

FIG. 12(a) is a semi-transparent plan view of a semiconductor device 300′ according to a modification. This modification is a modification corresponding to the semi-transparent plan view of the semiconductor device 300 illustrated in FIG. 5.

As illustrated in FIG. 12(a), five power semiconductor elements 155 forming the upper arm circuit are arranged in each of two rows on the second conductor plate 431. Similarly, five power semiconductor elements 157 forming the lower arm circuit are arranged in each of two rows on the fourth conductor plate 433. A wiring substrate 372 is provided on the conductor plates 431 and 433 between the respective placement of the power semiconductor elements 155 and 157 arranged in parallel. Signal wiring, which connects the power semiconductor elements 155 and 157 to signal terminals such as the lower arm gate terminal 325L, the lower-arm Kelvin emitter signal terminal 325K, the mirror emitter sense signal terminal 325M, and an upper arm gate terminal 325U, is provided on the wiring substrate 372. A chip resistor is disposed on signal wiring connected to the gates of the power semiconductor elements 155 and 157.

In a case where a power conversion device 200 is configured using the semiconductor device 300′, the power conversion device 200 may be required to have a higher output corresponding to a large current or a higher function such as failure diagnosis. However, because there is a limit to the current with which the power semiconductor elements 155 and 157 can be energized, it is effective to use the power semiconductor elements 155 and 157 in multi-parallel as illustrated in FIG. 12(a) in order to increase the output. In a case where the power semiconductor elements 155 and 157 are used in multi-parallel, the number of gate wirings for switching the power semiconductor elements is increased by the number of chips, and complicated wirings are required. Therefore, multilayering can be achieved in comparison with the lead frames, and the wiring can be laid out using the wiring substrate 372 corresponding to the fine wiring, thereby alleviating the wiring congestion in a case where the power semiconductor elements 155 and 157 are arranged in multi-parallel.

In addition, a gate resistor is required for the gate wiring in order to apply the charge required to drive the gates of the power semiconductor elements 155 and 157. Such a gate drive circuit is usually provided with a wiring substrate outside the semiconductor device and mounted on the wiring substrate, but in a case where the power semiconductor elements 155 and 157 are used in multi-parallel, it is desirable to provide a gate resistor for each element in order to prevent a malfunction. For this reason, the wiring substrate 372 on which the gate resistor is mounted as a chip resistor is built into the semiconductor device 300′. In a case where such a wiring substrate 372 is mounted, the total surface area of the close contact region between the conductor plates 430 and 431 and the insulation sheets 440 and 441 is greater than the total surface area of the element joining region 462 of the power semiconductor elements 155 and 157, and the pressure applied to the close contact region between the conductor plates 430 and 431 and the insulation sheets 440 and 441 is significantly reduced. Therefore, providing the resin filling space 460 described above is effective in reducing the total surface area of the close contact region to improve the insulation properties.

FIG. 12(b) is a cross-sectional view of a semiconductor device 300′ according to a modification. FIG. 12(b) is a cross-sectional view taken along line B-B illustrated in FIG. 12(a). FIG. 12(a) illustrates a cross-sectional view of a state in which the first conductor plate (upper arm circuit emitter side) 430, the first sheet member (emitter side) 440, and the cooling member 340 are provided.

In FIG. 12(b), as described with reference to FIG. 2, the emitter-side conductor plate 430 has the element joining region 462 joining the power semiconductor element 155, and the connection region 463 connecting the element joining region 462, and has the projection 461 immediately above the element joining region 462.

The projection 461 adheres to the insulation sheet 440 in the close contact region 464. In the connection region 463, a resin filling space 460 is formed between the insulation sheet 440 and the first conductor plate 430, and the resin filling space 460 is filled with the resin member 360 in the transfer molding process.

Similarly to the conductor plate 430 on the emitter side, the conductor plate 441 on the collector side is also formed having the projection 461 and the resin filling space 460. Because the resin filling space 460 is also provided on the collector side, the terminal is clamped, in the metal mold clamping of the transfer molding process, by the metal mold clamp, and thus there is no design restriction in pressing the conductor plate on the collector side against the insulation sheet 441, thereby improving the degree of design freedom.

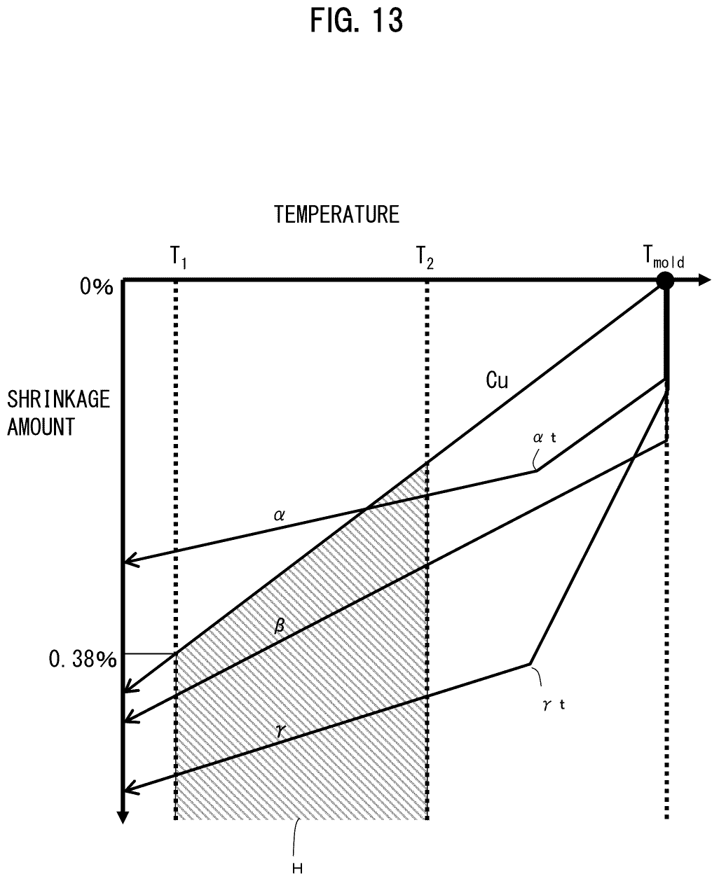

FIG. 13 is a diagram illustrating a relationship between a shrinkage amount of the resin member 360 and temperature. The horizontal axis represents the temperature, and the vertical axis represents the amount of shrinkage.

In a case where the glass transition temperatures at and γt are lower than Tmold, the resin members α and γ shown in FIG. 13 shrink by a large amount of shrinkage up to the glass transition temperatures αt and γt, respectively, and when the temperature becomes lower than the glass transition temperatures αt and γt, the resin members α and γ shrink by a smaller amount of shrinkage. In a case where the glass transition temperature is lower than Tmold, the resin member β shrinks by a constant amount of shrinkage. T1 is the minimum value of the usage environment temperature of the semiconductor device 300′, T2 is the maximum value of the usage environment temperature, where T1 is −40° C. and T2 is 125° C., for example. Tmold is, for example, 175° C. In this temperature range, in a case where the amount of shrinkage is greater than for copper Cu, that is, in a case where the amount of shrinkage of the resin member 360 falls within the hatched region H illustrated in FIG. 13, as described below, protrusions 466 oriented toward the resin filling space 460 can be provided on the insulation sheets 440 and 441 in the operating temperature range T1 to T2.

The principle behind forming the protrusions 466 on the insulation sheets 440 and 441 on the projections 461 and in the resin filling spaces 460 will be described with reference to FIG. 13. For example, the resin member 360 is injected into the transfer mold at a Tmold temperature of 175° C. Attention is directed toward shrinkage of the constituent members of the semiconductor device 300′ in the Z-axis direction by taking the dimensions immediately after injection as a reference. When the constituent members are viewed from the emitter side toward the collector side, the insulation sheet 440, the conductor plate 430, the solder, the power semiconductor element 155, the solder, the conductor plate 431, and the insulation sheet 441 are formed. The insulation sheets 440 and 441 are formed of resin insulation layers 442 and 443 having a thickness of 100 μm to 500 μm, and a metal foil 444 having a thickness of 30 μm to 200 μm. The conductor plates 430 and 431 are made of a copper-based material having a thickness of 1 mm to 5 mm. The solder is made of a tin-based material having a thickness of 50 μm to 200 μm. The power semiconductor element 155 is made of a silicon-based material having a thickness of 80 μm to 200 μm. The components are made of various materials; however, according to the present embodiment, the amount of shrinkage in the Z-axis direction of each of these components will be described by representing a copper-based material which is the thickest constituent material and approximating the amount of thermal shrinkage of pure copper Cu.

The resin member 360 is cured and shrunk by the progress of the curing reaction after the resin member 360 is injected into the transfer mold. The curing shrinkage amount varies depending on the composition of the resin member 360. The curing shrinkage amount varies depending on the ratio of the epoxy resin component that undergoes a curing reaction and the ratio of the other filler that does not undergo a curing reaction, and the greater the ratio of the epoxy resin component, the greater the curing shrinkage amount. Even when the ratio of the epoxy resin component is the same, the greater the ratio of the epoxy group as a reactive component in the epoxy resin component, the greater the curing shrinkage amount. The semiconductor device 300′ extracted from the metal mold of the transfer mold is cooled to room temperature. In a case where the glass transition temperature is lower than Tmold, shrinkage occurs at a high shrinkage ratio up to the glass transition temperature, and when the glass transition temperature is lower than the glass transition temperature, shrinkage occurs at a shrinkage ratio lower than the glass transition temperature. In a case where the glass transition temperature is higher than Tmold, shrinkage occurs at a constant shrinkage ratio. T1 is the minimum value of the usage environment temperature of the semiconductor device 300′, T2 is the maximum value of the usage environment temperature, where T1 is −40° C. and T2 is 125° C., for example. In this temperature range, in a case where the amount of shrinkage is greater than Cu, that is, in a case where the amount of shrinkage of the resin member 360 falls within the hatched region H, the resin member 360 shrinks more than Cu in the operating temperature range, and thus protrusions 466 are formed on the insulation sheets 440 and 441. In the modification of the present embodiment, by using the resin members β and γ illustrated in FIG. 13 as the resin member 360, the protrusions 466 can be formed on the insulation sheets 440 and 441.

By providing the protrusions 466 on the insulation sheets 440 and 441, the projection 461 serving as a main heat dissipating portion easily abuts on the cooling member 340 via the heat conduction member 453 and the insulation sheets 440 and 441, and the cooling performance can be improved. Furthermore, because the protrusions 466 are provided, the heat conduction member 453 can be thickened locally in the region where the protrusions 466 are formed, and in the case of using the adhesion-type heat conduction member 453, the stress can be reduced and the adhesion can be maintained for a long period of time, thus affording the advantageous effect of improving reliability. In addition, in a case where a non-adhesive-type heat conduction member 453 is to be used, the protrusions 466 hold the heat conduction member 453 and suppress the reduction in heat resistance caused by pump-out, thus affording the advantageous effect of improving reliability.

FIG. 14 is a circuit diagram of a power conversion device 200 employing semiconductor devices 300, 300′.

The power conversion device 200 includes inverter circuits 140 and 142, an auxiliary inverter circuit 43, and a capacitor module 500. The inverter circuits 140 and 142 include a plurality of semiconductor devices 300 and 300′, and a three-phase bridge circuit is configured by connecting the plurality of semiconductor devices 300 and 300′. In a case where the current capacity is large, the semiconductor devices 300 and 300′ are further connected in parallel, and the parallel connection is performed corresponding to each phase of the three-phase inverter circuit, thus making it possible to handle an increase in current capacity. In addition, by connecting in parallel the active elements 155 and 157 and the diodes 156 and 158, which are power semiconductor elements built into the semiconductor devices 300 and 300′, it is also possible to handle an increase in current capacity.

The inverter circuit 140 and the inverter circuit 142 have the same basic circuit configuration, and basically the same control method and operation. Because an outline of the circuit operation of the inverter circuit 140 and the like is well known, a detailed description thereof will be omitted here.

The upper arm circuits of the inverter circuits 140 and 142 include an upper-arm active element 155 and an upper-arm diode 156 as power semiconductor elements for switching, and the lower arm circuit includes a lower-arm active element 157 and a lower-arm diode 158 as power semiconductor elements for switching. The active elements 155 and 157 perform switching operations in response to a drive signal outputted from one or the other of the two driver circuits constituting the driver circuit 174, and convert the DC power supplied from the battery 136 into three-phase AC power.

The active element 155 of the upper arm circuit and the active element 157 of the lower arm circuit include a collector electrode, an emitter electrode, and a gate electrode. The diode 156 of the upper arm circuit and the diode 158 of the lower arm circuit include two electrodes, namely, a cathode electrode and an anode electrode. As shown in FIG. 6, the cathode electrodes of the diodes 156 and 158 are electrically connected to the collector electrodes of the IGBTs 155 and 157, respectively, and the anode electrodes are electrically connected to the emitter electrodes of the active elements 155 and 157, respectively. As a result, the current flows in the forward direction from the emitter electrode to the collector electrode of the upper-arm active element 155 and the lower-arm active element 157.

Note that a metal oxide semiconductor field effect transistor (MOSFET) may be used as the active element, and in this case, the diode 156 for the upper arm and the diode 158 for the lower arm are unnecessary.

The positive electrode-side terminal 315B and the negative electrode-side terminal 319B of each of the upper and lower arm series circuits are connected to a capacitor-connection DC terminal of the capacitor module 500. AC power is generated in each of the connecting parts of the upper arm circuit and the lower arm circuit, and the connecting parts are connected to the AC-side terminals 320B of the semiconductor devices 300 and 300′. The AC-side terminals 320B of the semiconductor devices 300 and 300′ of the respective phases are connected to the AC output terminals of the power conversion device 200, and the generated AC power is supplied to the stator winding of the motor generator 192 or 194.

The control circuit 172 generates a timing signal for controlling switching timing of the upper-arm active element 155 and the lower-arm active element 157 on the basis of input information from a control device, a sensor (for example, a current sensor 180), or the like on the vehicle side. The driver circuit 174 generates a drive signal for switching the upper-arm active element 155 and the lower-arm active element 157 on the basis of the timing signal outputted from the control circuit 172. Note that reference sign 181 denotes a connector.

The upper-arm and lower-arm series circuits include a temperature sensor (not illustrated), and temperature information of the upper-arm and lower-arm series circuits is inputted to the control circuit 172. Voltage information on the DC positive electrode side of the upper-arm and lower-arm series circuits is inputted to the control circuit 172. The control circuit 172 performs over-temperature detection and overvoltage detection on the basis of these pieces of information, and in a case where over-temperature or overvoltage is detected, stops the switching operation of all the upper-arm active elements 155 and lower-arm active elements 157 and protects the upper-arm and lower-arm series circuits from over-temperature or overvoltage.

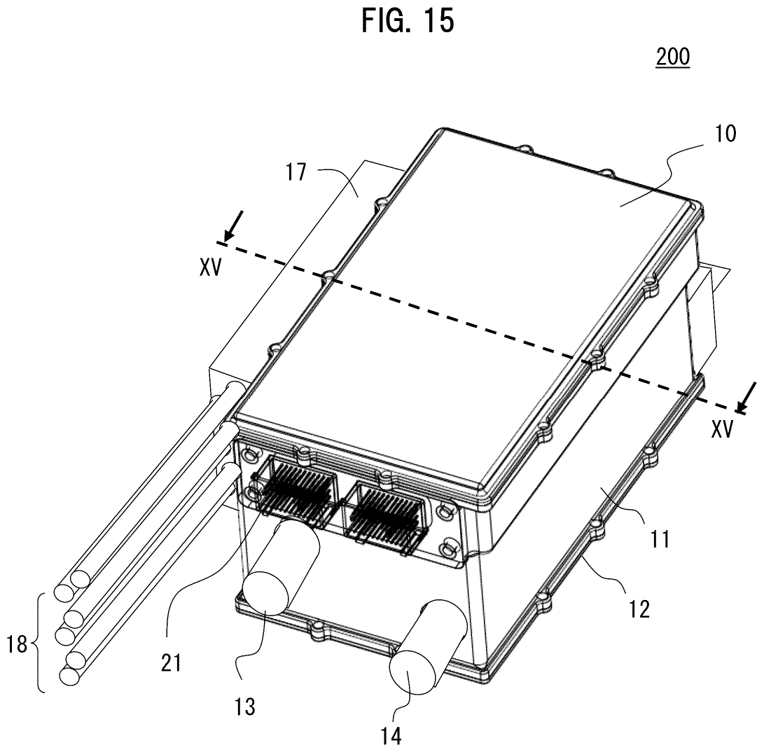

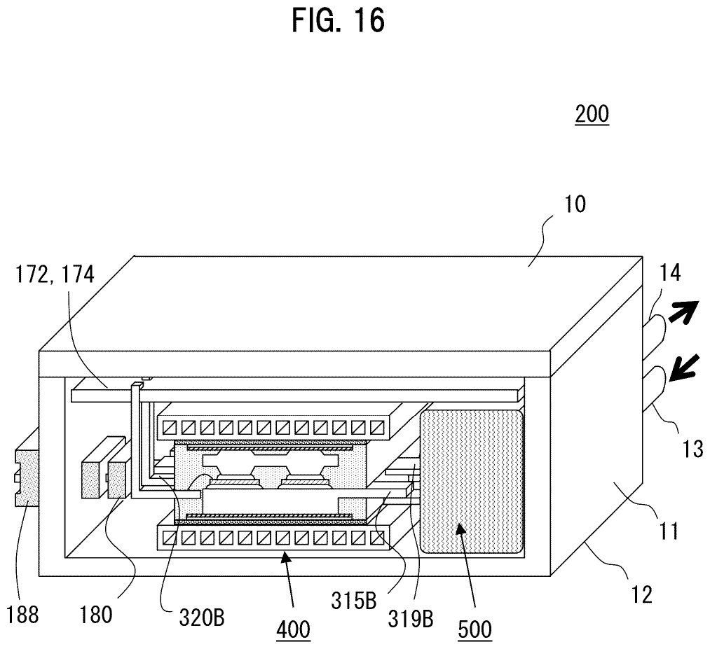

FIG. 15 is an external perspective view of the power conversion device 200 illustrated in FIG. 14, and FIG. 16 is a cross-sectional view taken along line XV-XV of the power conversion device 200 illustrated in FIG. 15.

The power conversion device 200 includes a housing 12 that includes a lower case 11 and an upper case 10 and that is formed in a substantially rectangular parallelepiped shape. An electric circuit body 400, a capacitor module 500, and the like are accommodated inside the housing 12. The electric circuit body 400 has a cooling flow path, and a cooling water inflow pipe 13 and a cooling water outflow pipe 14 that communicate with the cooling flow path protrude from one lateral surface of the housing 12. As illustrated in FIG. 16, the lower case 11 has an opening on the upper side (Z direction), and the upper case 10 is attached to the lower case 11 by closing the opening of the lower case 11. The upper case 10 and the lower case 11 are formed of an aluminum alloy or the like, and are sealed and fixed to the outside. The upper case 10 and the lower case 11 may be integrated. Because the housing 12 has a simple rectangular parallelepiped shape, attachment to a vehicle or the like is straightforward, and production is facilitated.

A connector 17 is attached to one lateral surface of the housing 12 in the longitudinal direction, and an AC terminal 18 is connected to the connector 17. A connector 21 is provided on the surface from which the cooling water inflow pipe 13 and the cooling water outflow pipe 14 are led out.

As illustrated in FIG. 16, an electric circuit body 400 is accommodated in the housing 12. A control circuit 172 and a driver circuit 174 are arranged above the electric circuit body 400, and a capacitor module 500 is accommodated on the DC terminal side of the electric circuit body 400. By arranging the capacitor module 500 at the same height as the electric circuit body 400, the power conversion device 200 can be thinned, and the degree of freedom in installation on the vehicle is improved. The AC-side terminal 320B of the electric circuit body 400 penetrates the current sensor 180 and is joined to a bus bar 361. The positive electrode-side terminal 315B and the negative electrode-side terminal 319B, which are DC terminals of the semiconductor devices 300 and 300′, are each joined to the positive-electrode and negative-electrode terminals 362A and 362B of the capacitor module 500, respectively.

The embodiments described above afford the following actions and effects.

(1) Semiconductor devices 300 and 300′ include a plurality of power semiconductor elements 155, 156, 157, and 158, conductor plates 430, 431, 432, and 433 to which the plurality of power semiconductor elements 155, 156, 157, and 158 are joined, insulation sheets 440 and 441 bonded to the surface of conductor plates 430, 431, 432, and 433 on the opposite side from the side of the plurality of semiconductor elements, and a resin member 360 sealing the plurality of power semiconductor elements 155, 156, 157, and 158, the insulation sheets 440 and 441, and the conductor plates 430, 431, 432, and 433. The conductor plates 430, 431, 432, and 433 each have a plurality of element joining regions 462 to which the plurality of power semiconductor elements 155, 156, 157, and 158 are joined, respectively, and a connection region 463 provided between the plurality of element joining regions 462, wherein the insulation sheet-side surface of the conductor plates 430, 431, 432, and 433 in the element joining regions 462 protrudes from the insulation sheet-side surface of the connection region 463 and is bonded to the insulation sheets 440 and 441, and
wherein the resin member 360 is added between the insulation sheets 440 and 441 and the insulation sheet-side surface of the conductor plates 430, 431, 432, and 433 in the connection region 463. As a result, it is possible to provide highly reliable semiconductor devices 300 and 300′ having enhanced insulation properties afforded by the insulation sheets 440 and 441.

The present invention is not limited to or by the above-described embodiments, and various modes conceivable within the scope of the technical ideas of the present invention are also included within the scope of the present invention as long as the features of the present invention are not impaired. Moreover, the above-described embodiments and modifications may be combined.

### REFERENCE SIGNS LIST

10 upper case
11 lower case
12 housing
13 cooling water inflow pipe
14 cooling water outflow pipe
17, 21 connector
18 AC terminal
43, 140, 142 inverter circuit
155 first power semiconductor element (upper arm circuit active element)
156 first power semiconductor element (upper arm circuit diode)
157 second power semiconductor element (lower arm circuit active element)
158 second power semiconductor element (lower arm circuit diode)
172 control circuit
174 driver circuit
180 current sensor
181 connector
192, 194 motor generator
200 power conversion device
300, 300′ semiconductor device
315B positive electrode-side terminal
319B negative electrode-side terminal
320B AC-side terminal
325 signal terminal
325K Kelvin emitter signal terminal
325L lower arm gate terminal
325M mirror emitter signal terminal
325U upper arm gate terminal
340 cooling member
360 resin member
372 wiring substrate
400 electric circuit body
430 first conductor plate (upper arm circuit emitter side)
431 second conductor plate (upper arm circuit collector side)
432 third conductor plate (lower arm circuit emitter side)
433 fourth conductor plate (lower arm circuit collector side)
440 first insulation sheet (emitter side)
441 second insulation sheet (collector side)
442 first resin insulation layer (emitter side)
443 second resin insulation layer (collector side)
444 metal foil
453 heat conduction member
460 resin filling space
461 projection
462 element joining region
463 connection region
464 close contact region
465 void
466 protrusion
500 capacitor module
601 transfer molding device
602 spring

1. A semiconductor device, comprising: a plurality of semiconductor elements; a conductor plate to which the plurality of semiconductor elements are joined; an insulation sheet which is bonded to the face of the conductor plate on the opposite side from the side of the plurality of semiconductor elements; and a resin member that seals the plurality of semiconductor elements, the insulation sheet, and the conductor plate,
wherein the conductor plate includes a plurality of element joining regions to which each of the plurality of semiconductor elements is joined, and a connection region provided between the plurality of element joining regions, wherein the insulation sheet-side surface of the conductor plate in the element joining regions protrudes from the insulation sheet-side surface of the connection region and is bonded to the insulation sheet, and wherein the resin member is added between the insulation sheet and the insulation sheet-side surface of the conductor plate in the connection region.

2. The semiconductor device according to claim 1,
wherein the insulation sheet includes a resin insulation layer, and wherein the resin insulation layer and the resin member are in close contact with each other due to penetration by a resin component.

3. The semiconductor device according to claim 1,
wherein a resin filling space filled with the resin member is formed between the insulation sheet-side surface of the connection region and the insulation sheet, and wherein the resin member in the resin filling space is connected to a resin member that seals the plurality of semiconductor elements, the insulation sheet, and the conductor plate.

4. The semiconductor device according to claim 3,
wherein the thickness of the resin filling space is equal to or greater than the thickness of the insulation sheet.

5. The semiconductor device according to claim 4,
wherein the insulation sheet includes a laminated structure of a resin insulation layer and a metal foil, and
wherein the thickness of the resin filling space is equal to or greater than the thickness of the resin insulation layer.

6. The semiconductor device according to claim 1,
wherein the conductor plate and the insulation sheet are arranged on both surfaces of the plurality of semiconductor elements, and
wherein a resin filling space filled with the resin member is formed between the conductor plate and the insulation sheet arranged on both surfaces and between the insulation sheet-side surface of the connection region and the insulation sheet, respectively.

7. The semiconductor device according to claim 6,
wherein the insulation sheet has a protrusion oriented toward the resin filling space.

8. A power conversion device, comprising the semiconductor device according to claim 1, wherein DC power is converted into AC power.
